(19) United States
(12) Patent Application Publication
(10) Pub. No.: US 2024/0006264 A1
(43) Pub. Date: Jan. 4, 2024

(54) Apparatus with a Porous Body for Receiving a Heat Quantity and Method for Providing an Apparatus

(71) Applicant: Fraunhofer-Gesellschaft zur Foerderung der angewandten Forschung e.V., Munich (DE)

(72) Inventors: Thomas LISEC, Itzehoe (DE); Malte PAESLER, Itzehoe (DE); Holger KAPELS, Itzehoe (DE); Bjoern GOJDKA, Itzehoe (DE)

(21) Appl. No.: 18/368,967

(22) Filed: Sep. 15, 2023

Related U.S. Application Data
(63) Continuation of application No. PCT/EP2022/057012, filed on Mar. 17, 2022.

(30) Foreign Application Priority Data
Mar. 18, 2021 (DE) 102021202630.3

(51) Int. Cl. H01L 23/373; H01L 23/46; H01L 23/15

(52) U.S. Cl. CPC H01L 23/3733; H01L 23/46; H01L 23/3735; H01L 23/15

(57) ABSTRACT

An apparatus includes a substrate and a heat source structure connected to the substrate and configured to provide a heat quantity. Furthermore, a porous body including connected particles is provided, wherein gaps between the particles form fluidically connected cavities. The porous body is configured to at least partially receive the heat quantity of the heat source structure.

### CROSS-REFERENCES TO RELATED APPLICATIONS

This application is a continuation of copending International Application No. PCT/EP2022/057012, filed Mar. 17, 2022, which is incorporated herein by reference in its entirety, and additionally claims priority from German Application No. DE 10 2021 202 630.3, filed Mar. 18, 2021, which is incorporated herein by reference in its entirety.

### BACKGROUND OF THE INVENTION

The present invention concerns an apparatus with a substrate and a heat source structure connected thereto and providing a heat quantity, and a porous body configured to at least partially receive this heat quantity. The present invention further concerns a method for manufacturing such an apparatus. In addition, the present disclosure concerns thermally resistant inductances.

Active electronic components such as power transistors or LEDs generate significant heat quantities in their operation. This makes passive components located in close proximity experience significant thermal stress. Modern control methods of active components additionally lead to a shift of a part of the thermal losses to passive components. Miniaturization of electronic systems tends to go along with the need for greater capabilities and an increased power density. Larger and larger heat quantities are released on ever-smaller boards (so-called interposers). Thermal resistance of the components integrated thereon as well as the temperature rise of the system in general become more and more important.

GaN transistors can be permanently operated at temperatures of over 200° C. so that they my for the basis for particularly high-performance voltage converters in the frequency range of several MHz up to the GHz range. To realize very compact circuits, passive components such as capacitors and coils that may permanently endure such high operation voltages are needed in an appropriate design size. Monolithic integration of components amplifies this effect since heat dissipation can only occur via the mutual substrate. While corresponding capacitors are available, there are no micro-coils with sufficiently high inductance and high thermal resistance. There is a similar problem in the realization of compact LED arrays including the driver component. For thermal decoupling, the LED and the driver electronics are currently installed on separate carriers and are connected via bond wires. Here, thermally resistant components, including micro-coils, with a sufficiently high inductance for a further miniaturization of the system would be desirable as well.

Discrete wound air-core coils that are often responsible for the majority of the dimensions of an electronic component form the conventional technology for miniaturized coils. The smallest coils are easy to create in a planar design size on a semiconductor substrate. In principle, their thermal stability is very good, however, the inductance/area ratio is limited to a few nH/mm². Since it is only possible to deposit thin layers by means of standard methods of the IC technology, the winding number is limited due to the quickly rising serial resistance. The type of air-core coil is used at very high frequencies and very low powers. The integrated transformers of the iCoupler series from Analogue Devices for the insulation of digital signal lines as a replacement for opto-couplers, consisting of stacked planar coils with a very thick polyimide layer therebetween [1], are an example for this. Under the name of “isoPower,” the same technology is used for providing insulated supply voltages of 5V. Due to the very low inductances, isoPower only works effectively at frequencies around 300 MHz and is limited in its power to approximately 50 mW due to dynamic losses.

For a power transfer, e.g. in the range of around 20 MHz and more, coils having a core are used. Soft magnetic materials and alloys in the form of very thin layers are available as a core material in the IC technology. Ferrites, which are preferred in conventional coils at higher frequencies, cannot be manufactured with justifiable effort. Planar coils with a galvanically deposited NiFe casing were developed at the Tyndall-Institute in Cork [2]. DC-DC converters built by using such coils achieve efficiencies of 74% at 20 MHz, or 70% at 40 MHz. The majority of the losses are due to eddy currents [3] that quickly lead to a strong temperature increase of the component. To suppress any currents, the casing in the coil from Intel [4] is configured from many thin electrically insulated NiFe metal layers. Since Tyndall [2] and Intel [4] both use organic materials to electrically insulate the coil and the casing, the thermal resistance of the components is limited. Ferric also uses a stack of electrically insulated metal layers for integrated solenoid coils with up to 300 nH/mm² [5].

Thus, there is a need for thermally resistant apparatuses.

### SUMMARY

An embodiment may have an apparatus, comprising: a substrate; a heat source structure connected to the substrate and configured to provide a heat quantity; and a porous body comprising particles connected by a coating, wherein gaps between the particles form fluidically connected cavities; wherein the porous body is configured to at least partially receive the heat quantity of the heat source structure.

Another embodiment may have a method for providing an apparatus, comprising: connecting, to a substrate, a heat source structure configured to provide a heat quantity; and arranging a porous body comprising particles connected by a coating so that gaps between the particles form fluidically connected cavities; so that the porous body is configured to at least partially receive the heat quantity of the heat source structure.

A core idea of the present invention is to have recognized that a porous body is suitable to receive a heat quantity of a heat source. Porous bodies comprise a high thermal resistance.

According to an embodiment, an apparatus includes a substrate and a heat source structure connected to the substrate and configured to provide a heat quantity. Furthermore, a porous body including connected particles is arranged, wherein gaps between the particles form fluidically connected cavities (or hollow spaces). The porous body is configured to at least partially receive the heat quantity of the heat source structure.

In this case, the connected particles may receive the heat quantity and transport it away via the fluidically connected cavities so that the porous body has overall a high thermal resistance (or stability), and, due its cooling effect, the apparatus has overall a high thermal resistance (or stability).

According to an embodiment, a method for providing an apparatus includes connecting, to a substrate, a heat source structure configured to provide a heat quantity. It further includes arranging a porous body including connected particles so that gaps between the particles form fluidically connected cavities. The method is carried out such that the porous body is configured to at least partially receive the heat quantity of the heat source structure.

According to an embodiment, a connection of these particles is done by carrying out atomic layer deposition, which enables an efficient thermally resistant (or stable) and cost-efficient connection.

### BRIEF DESCRIPTION OF THE DRAWINGS

Embodiments of the present invention will be detailed subsequently referring to the appended drawings, in which:

FIG. 1a shows a schematic side-sectional view of an apparatus according to an embodiment;

FIG. 1b shows a schematic side-sectional view of an apparatus according to an embodiment, wherein a porous body is arranged at a heat source structure;

FIG. 2 shows a schematic side-sectional view of a porous body according to an embodiment;

FIG. 3a shows a schematic side-sectional view of an apparatus according to an embodiment, wherein a porous body is integrated into a substrate;

FIG. 3b shows a schematic side-sectional view of an apparatus according to an embodiment, with porous bodies and substrate openings;

FIGS. 4a-b shows schematic side-sectional views of apparatuses according to embodiments, formed similarly as the apparatus from FIG. 3a, wherein an active element is arranged outside of a core area;

FIG. 5a shows a schematic side-sectional view of an apparatus according to an embodiment, wherein the active element is arranged adjacent to the porous body;

FIG. 5b shows a schematic side-sectional view of an apparatus according to an embodiment, wherein the porous body is at least partially integrated into the substrate, in contrast to the apparatus of FIG. 5a;

FIG. 6 shows a schematic perspective view of an apparatus according to an embodiment, wherein the heat source structure includes a passive element;

FIG. 7a shows a schematic perspective view of a part of the apparatus according to an embodiment, and to illustrate conductor path structures connected through the via structures;

FIG. 7b shows a partial section of the illustration of FIG. 7a;

FIG. 7c shows a schematic top view of a main side of the apparatus illustrated in FIG. 6;

FIGS. 8a-f show schematic side-sectional views to illustrate possible method steps corresponding to embodiments described herein; and

FIG. 9 shows a schematic flow diagram of a method for providing an apparatus according to an embodiment.

### DETAILED DESCRIPTION OF THE INVENTION

Before embodiments of the present invention are subsequently described in detail on the basis of the drawings, it is to be noted that identical and functionally identical elements, objects and/or structures, and elements, objects and/or structures having the same effect, are provided in the different figures with the same reference numerals so that the description of these elements illustrated in the different embodiments is interchangeable, or can be applied to each other.

Subsequently described embodiments are described in connection with a multitude of details. However, embodiments can also be implemented without any of these detailed features. In addition, embodiments are described using block circuit diagrams as a replacement of a detailed illustration for the sake of comprehensibility. In addition, details and/or features of individual embodiments can be readily combined unless explicitly noted otherwise.

Embodiments of the present invention concern porous bodies. They comprise connected particles, wherein gaps between the particles form fluidically connected cavities. In this case, the particles may comprise any material, however, advantageously they are thermally resistant (or stable). Thermally resistant is to be understood in relation to the respective application. In the context of the implementation as an integrated circuit, in particular in the power range, e.g. for driving/controlling LEDs and the like, temperature resistant is to be understood such that temperatures of at least 100° C., at least 150° C., at least 200° C. or more, in particular at least 250° C., at least 300° C. or at least 400° C., are admissible as permanent operation temperatures, i.e. the porous body is temperature-stable for a temperature in this range. This may be understood as an absence of a significant deformation, an absence of a significant degeneration of a material property or the like. In particular, this may be regarded in combination with a heat source of the apparatus configured to release a heat quantity. The same reaches the porous body at least partially so as to heat the it. Thus, the heat source may be configured to heat the porous body to the indicated temperatures of at least 100° C., at least 150° C., at least 200° C., at least 250° C., at least 300° C., or at least 400° C.

Beyond the temperature resistance, the particles may comprise further functionalities. For example, using the porous body as a coil core may be desired. To this end, according to embodiments, the particles include soft magnetic materials. In other implementations, the porous body may be used as a mechanical and/or chemical filter. In such cases, e.g., the use of soft magnetic particles is less relevant than properties for mechanical durability or the like.

Porous bodies described in connection with embodiments described herein comprise particles that are connected, e.g., by using a coating. For example, this coating may be comparably thin so that cavities between the particles remain unfilled by the coating. In addition, the cavities are fluidically connected, enabling that a fluid flows through neighbouring cavities. In some embodiments of the present invention, the porous body may be formed for a passage (or flow) of a fluid, wherein a fluid enters the body and exits the body. According to other embodiments, e.g., an outer surface of the porous body is coated with a passivation layer or the like, which may prevent an entry or exit of the fluid into the body or out of the body. Such a layer may be locally opened; however, this is not necessarily required.

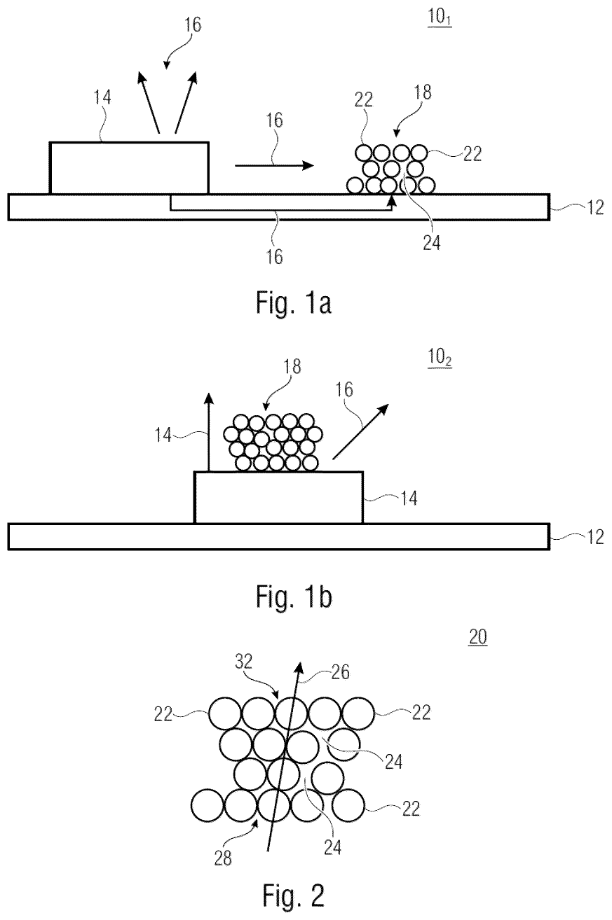

FIG. 1a shows a schematic side-sectional view of an apparatus 10₁ according to an embodiment. The apparatus 10₁ includes a substrate 12. The substrate 12 may include a semiconductor material and may be formed with one layer or several layers, for example. One or several of these layers may be formed to be electrically conductive and/or electrically insulating, as is common in the IC and MEMS field. The substrate 12 may be formed to be planar; however, it may also have a topography, i.e. bumps and/or depressions. Alternatively or additionally to semiconductor materials, the substrate 12 may also be formed as a conductor board or the like. In other words, the substrate 12 may be a printed circuit board (PCB) and/or a direct bonded copper (DBC, or a direct copper bond (DCB)), a semiconductor material, a glass material or combinations therefrom, for example.

The apparatus 10₁ includes a heat source structure connected to the substrate 12 and configured to provide a heat quantity 16.

The apparatus 10₁ includes a porous body 18 including connected particles 22. Gaps 24 between the particles 22 form fluidically connected cavities. The porous body 18 is configured to receive at least a part of the heat quantity 16. Receiving the heat quantity of the heat source structure 14 is understood such that the heat source structure 14 heats the porous body 18 to a relevant extent, as initially described. Particularly advantageous embodiments refer to operation temperatures of 200° C. or 250° C., e.g. at least 400° C. or more, wherein other temperature ranges are also possible, as initially described.

In this case, the heat source structure 14 may be a single component or a group of components. For example, the heat source structure 14 may include a power component, such as a driver or the like, and may be used for LEDs. Alternatively or additionally, any other circuit with one or several components may be arranged. Alternatively or additionally to such active components, the heat source structure 14 may be formed entirely or partially by passive elements. In this way, for example, the heat source structure 14 may provide at least a part of a coil winding structure. In particular, in high frequency operation, coil windings may provide a relevant heat quantity that may be received and/or dissipated by the porous body 18. In this case, it is possible, but not required, that the heat source structure 14 fully provides the coil windings. According to embodiments, the heat source structure is formed as a semi-coil or the like that is completed to an electrical coil in connection with a further apparatus or a further element. For example, this may be referred to as semi-coil, wherein the same lacks conductor paths in an element plane, said conductor paths being implemented, e.g., by conductor paths on a further carrier substrate, so that a connection of the heat source structure 14 and the additional substrate then completes the coil.

This means that the heat source structure may form a part of an electrical coil or may form a full coil. However, this is only a non-limiting example for the heat source structure including at least a part of an electrically passive element and the electrically passive element being configured to generate at least a part of the heat quantity under the impact of electrical energy.

FIG. 1b shows a schematic side-sectional view of an apparatus 10₂ according to an embodiment. Essentially, the same comprises the same elements as the apparatus 10₁. In contrast to the apparatus 10₁, however, the porous body is not fixed to the substrate 12, but to the heat source structure 14. According to further embodiments, the porous body is integrated fully or partially into the substrate 12, alternatively or additionally, the heat source structure 14 is integrated fully or partially into the substrate, and/or the heat source structure 14 is not directly connected to the substrate 12, but indirectly, e.g., by means of the porous body 18 or other intermediate heat-transporting elements.

FIG. 2 shows a schematic side-sectional view of a porous body 20 according to an embodiment, e.g., which may be used as a porous body 18, e.g. in the apparatus 10₁ and/or 10₂. The porous body 20 includes a multitude of particles 22 that may be formed so as to be identical, however, that may also include several different particles in sum. For example, the particles may differ with respect to a particle material, a particle coating, and/or a particle diameter, or may be formed equally. Exemplary particle diameters are between at least 1 μm and up to 25 μm in an advantageous but non-limiting implementation, for example. However, in some particle powders, the particle size may also vary significantly, which is why in such a case a value range of, e.g., 1 μm-25 μm is understood as mean values (so-called D50). In the context of embodiments, some powders, such as NdFeB powder, may vary by a D50 value of 5 μm, e.g. from 1 μm to 10 μm. NdFeB powders with a D50 value of 25 μm already vary by 1 μm to 100 μm. Even if the particles 22 are formed so as to be approximately round, in embodiments, there may be other shapes of particles, e.g. planar particle surfaces or the like. On the other hand, round particles enable a particularly small contact area of neighbouring particles so that passage of a fluid 26 through the gaps 24 between the particles 22 remains as undisturbed as possible. However, in this case there has to be an assessment as to obtain a minimum durability of the porous structure with a decreasing contact area.

For a passage of the fluid 24, the porous body may comprise an entry area 28 for an entry of the fluid 26 and an exit area 32 fluidically coupled to the entry area 28 by means of the fluidically connected cavities 24 for an exit of the fluid. The porous body may be configured to release, during the passage of the fluid 26, at least a part of the received heat quantity 16 to the fluid so as to cool the porous body. In this case, not only the porous body may be cooled, but the heat structure 14 may also be cooled directly or indirectly by generating a heat gradient. A position or orientation of the entry area 28 and/or the exit area 32 may be influenced in the form of the porous body 20. Alternatively or additionally, the porous body may be coated at an outside with a fluidically less permeable layer or a sealed layer that is locally opened for providing the entry area 28 and/or the exit area 32. Such a layer may be only partially arranged at the porous body, and one or several sides may be spared fully or partially, for example. Alternatively or additionally, a position, extension, and/or orientation of the entry area 28 and/or the exit area 32 may also be defined by generating a fluid flow for the fluid 26. This means that the passage of the fluid 26 may be generated fully or in part actively so as to provide an active cooling. A direction with which the fluid is guided may define the entry area 28 and/or the exit area 32. In contrast to an active cooling, the passage may also be generated at least partially with the dissipated heat quantity, e.g. in the context of a passive cooling. Thus, for example, the heated fluid 26 may rise to higher positions and in lower positions, it may draw in fluid by generating a lower fluidic pressure, thereby creating a fluid flow.

According to some embodiments, the substrate 12 comprises a fluidic opening configured to guide the fluid 26 towards the entry area 28 or away from the entry area 32.

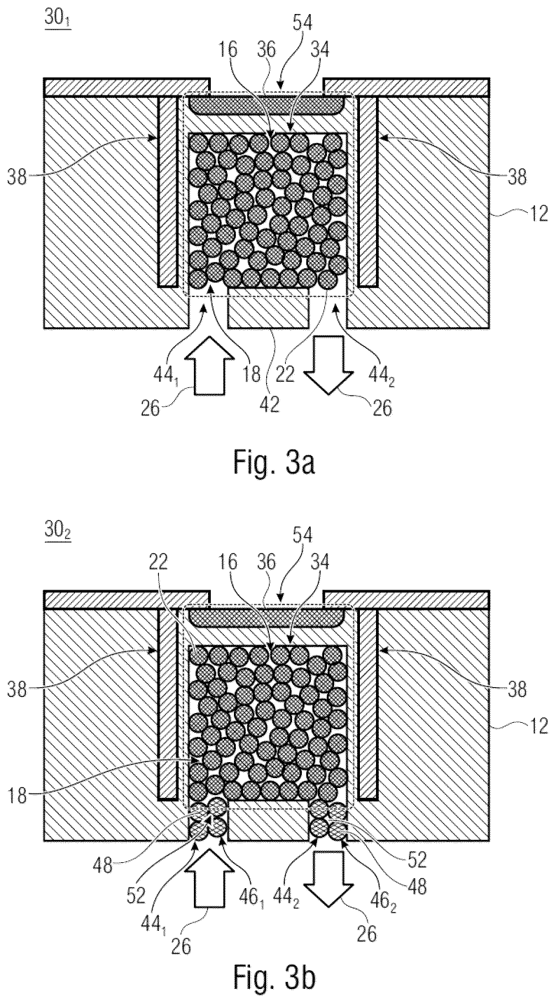

FIG. 3a shows a schematic side-sectional view of an apparatus 30₁ according to an embodiment, comprising several further developments to be implemented independently from one another, compared to the apparatus 10₁ and/or 10₂. On the one hand, the porous body 18 is integrated into the substrate 12. In an advantageous implementation, this may be achieved by a recess 34 being introduced into the substrate 12, by filling the particles 22 into the recess 34, and by solidifying the recess 34 by means of a coating chamber, i.e. by performing atomic layer deposition (ALD).

The apparatus 30₁ includes an active element as a part of the heat source structure, e.g. an LED, a driver for the same, or another active element. Diodes and/or transistors and/or integrated circuits may also be formed as active elements. An active element that may form at least a part of the heat source structure may be configured to generate a part of the non-illustrated heat quantity 16 under the impact of electrical energy. Alternatively or additionally, the apparatus 30₁ includes a passive element 38 also configured to generate at least a part of the non-illustrated heat quantity 16 under the impact of electrical energy. For example, the passive element 38 in the apparatus 30₁ is an element used for operating the active element 36, e.g. a coil, for which the porous body 18 simultaneously provides a coil core. To this end, the particles 22 may comprise a soft magnetic material, such as soft iron, FeSi, FeNi, FeCo, or other alloys or materials.

The recess 34 may be closed again in the context of manufacturing the apparatus 30₁, e.g. by depositing a substrate material, prior to arranging active or passive components, and/or by arranging a substrate portion 42. For example, such a deposition may be carried out by a layer deposition and/or by wafer bonding.

The apparatus 30₁ may be configured so that the substrate 12 comprises one or several fluidic openings 44₁ and/or 44₂ configured to let the fluid 26 through towards the entry area and/or away from the exit area of the porous body 18. A position of the fluidic openings 44₁ and/or 44₂ may at least partially determine a direction of the passage of the fluid.

FIG. 3b shows a schematic side-sectional view of an apparatus 30₂, structured similarly as the apparatus 30₁. Regardless of whether an active element 36 and/or a passive element 38 forms a part of the heat source structure, the openings 44₁ and/or 44₂ may each comprise porous structures 46₁ and/or 46₂, independently of each other, which partially or fully fill these openings 44₁ and 44₂, respectively. The porous structures 46₁ and/or 46₂ may similarly comprise particles 48 and form bodies that are formed by solidification of the particles 48 such as the porous bodies 18 and 20, respectively. In an embodiment, the particles 48 and particles of the porous body may be introduced successively in a substrate opening and may be solidified at the same time. Alternatively, the particles 48 may be introduced and solidified first, and the particles of the body 18 may be solidified thereafter, or vice versa. In an embodiment, the particles of the body 18 and the particles 48 may also be identical, or may originate from a mutual amount of particles.

In this case, the particles 48 may be equal or different from each other with respect to a size, shape, and/or characteristic, or may be equal or different from another with respect to the particles 22 of the porous body 18. However, it is possible to implement a functional separation, e.g., in that the particles 48 include a non-magnetic material, whereas the particles 22 include a soft magnetic material, in particular if the porous body 18 forms a coil core. Due to the connected particles 48, wherein gaps between the particles also form fluidically connected cavities 52, the porous structures 44₁ and/or 44₂ may enable protection against foreign particles as release of parts of the porous body 18 and/or may be used for the control of a flow of the fluid 26. Thus, e.g., swirls or the like may be adjusted, reduced, or prevented in a fluid 26.

In the illustrations of FIGS. 3a and 3b, the active element 36 may be arranged within a core area. The structure 38 may be formed as a coil additionally comprising the active element 36 within the core area 54.

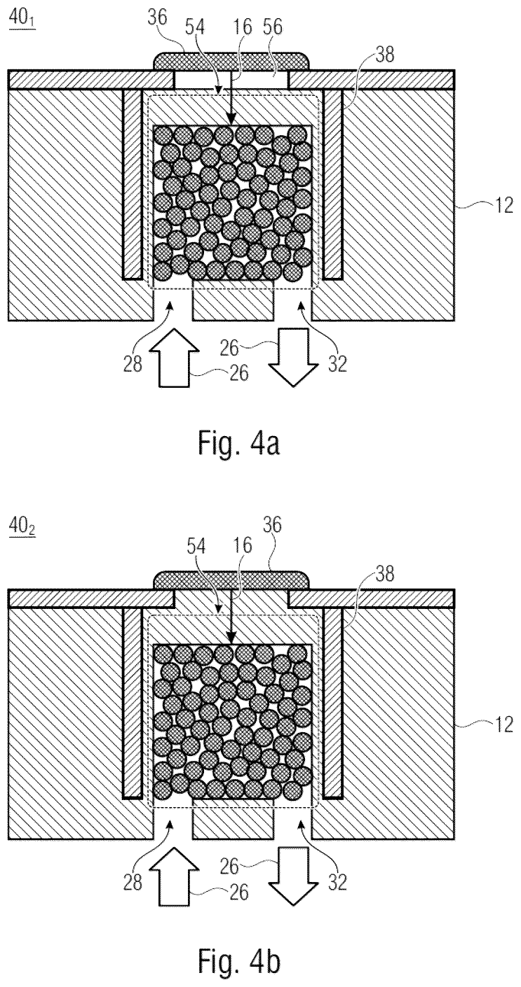

FIGS. 4a and 4b show schematic side-sectional views of apparatuses 40₁ and 40₂, respectively, formed similarly as the apparatus 30₁. Compared to the apparatus 30₁, the active element is arranged outside of the core area 54, but, as an example, is connected mechanically and/or electrically directly to the passive element 38. In this case, the apparatus 40₁ comprises a cavity 56 between the substrate 12 and the active element e.g. that may be used for controlling the heat flow. In contrast, the apparatus 40₂ comprises a substrate material at locations that are spared for forming the cavity 56 in the apparatus 40₁. For example, this may be made possible by the integration of conducting structures of the passive element 38 for forming a homogeneous surface and/or by filling the cavity 56 of the apparatus 40₁ with substrate material.

Optionally, a porous structure 46 may be arranged in the entry area 28 of the apparatus 40₁ and/or 40₂ and/or in an area of the exit area 32 of the apparatus 40₁ and/or 40₂.

Even though the heat quantity 16 is illustrated such that it emanates from the active element 36, when considering FIGS. 3a, 3b, 4a and 4b, a passive element formed as a coil may also provide a part of the heat quantity 16.

In the illustrations of FIGS. 3a, 3b, 4a, and 4b, the porous body 18 may provide at least a part of a functional element. In the examples illustrated, e.g., this is a coil core, while other functional elements, such as a transformer or the like, may also readily comprise a porous body 18 and/or 20 as a component. The functional element may provide a function of the overall apparatus and may be configured to maintain the function under the impact of the heat source. For example, in this case, the functional element may be associated with an operation of the heat source. This is particularly the case in the use of the functional element for the operation of the apparatus, e.g. if the active element is an LED or a driver for the same, and the coil is used for the operation of the LED, or the driver.

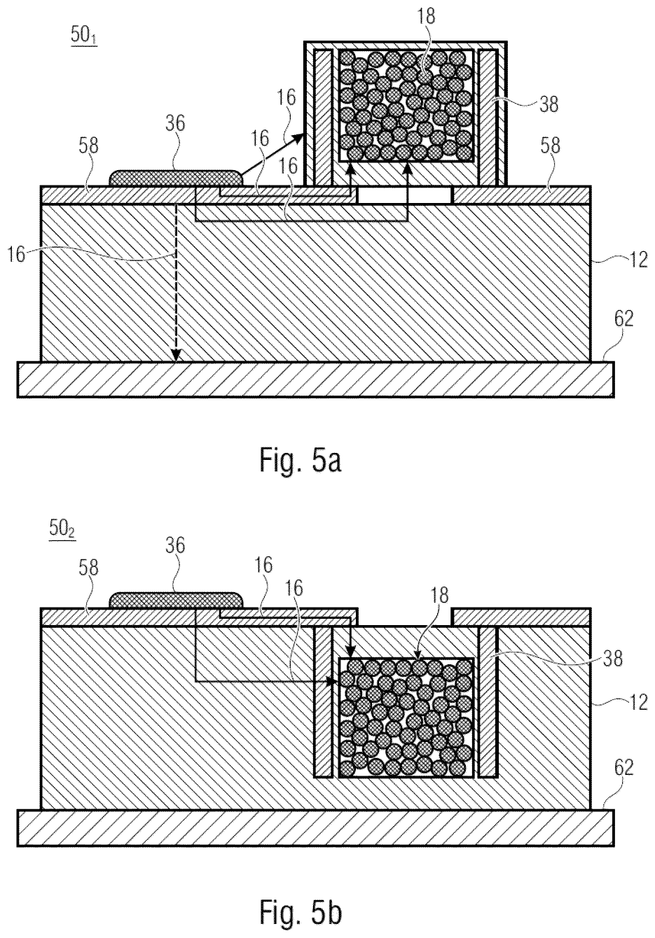

FIG. 5a shows a schematic side-sectional view of an apparatus 50₁ according to an embodiment. In this embodiment, the active element 36 may be arranged adjacent to the porous body 18 only exemplarily forming a part of the passive element 38. The passive element 38 may be connected to the active element 36 via conductor paths 58 that may enable a heat bridge between the porous body 18 and the active element 36, or the heat source structure, same as the substrate 12.

Optionally, a cooling body 62 may be connected to the substrate 12 in a thermally conductive manner. The cooling body 62 may enable additional heat dissipation of the heat quantity 16. Same as in the apparatuses 30₁, 30₂, 40₁ and 40₂, the heat source structure may include the active element 36 configured to provide at least a part of the heat quantity 16 under the impact of electrical energy. While, in the apparatuses 30₁ and 30₂, at least one coil winding of an electrical coil may extend around the active element 36, or, as shown for the apparatuses 40₁ and 40₂, the active element may be arranged at an outer side of the electrical coil, the active elements 36 of apparatus 50₁ is arranged adjacent to the substrate 12, however, in such a way that a relevant amount of the heat quantity 16 reaches the porous body 18 so as to heat the same. In this case, the heat source structure may also include the active element 36 and at least a part of an electrically passive heat source, e.g. the coil.

FIG. 5b shows a schematic side-sectional view of an apparatus 50₂ according to an embodiment. In contrast to the apparatus 50₁, the porous body 18 may be at least partially integrated into the substrate 12, which may also be understood such that in case of a schematic consideration of the porous body as a cube with six sides, at least five sides may be at least partially surrounded by substrate material of the substrate 12. However, the cooling body 62 may optionally be used for additional cooling.

The porous body of the apparatus body 50₂ and possibly also the apparatus 50₁ may be fully enclosed by the substrate material so that external fluid does not reach the porous body. Regardless, the porous body 18 may still receive a heat quantity 16 and may contribute in a temperature-stable way to the operation of the passive element 38 and/or the active element 36.

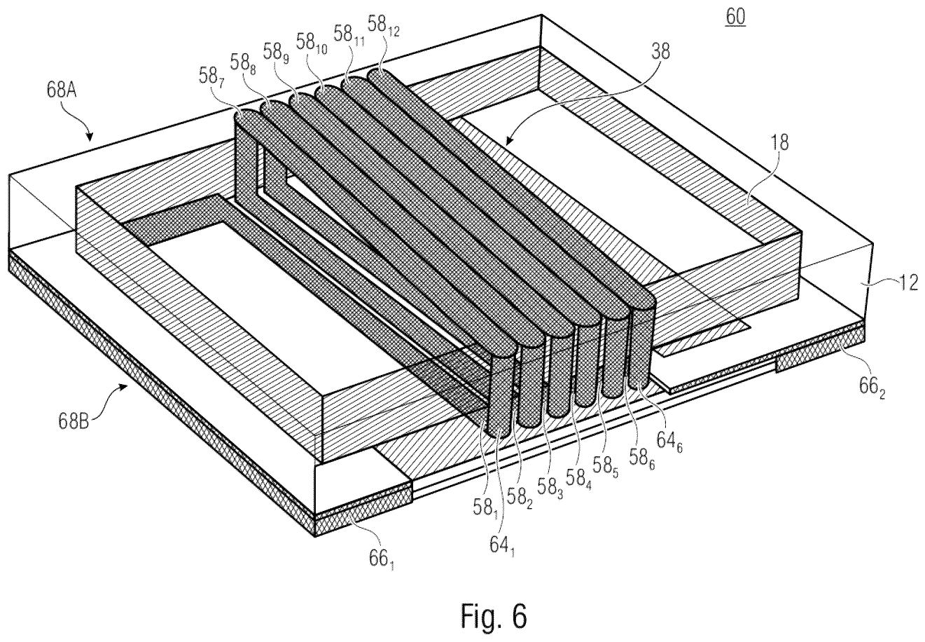

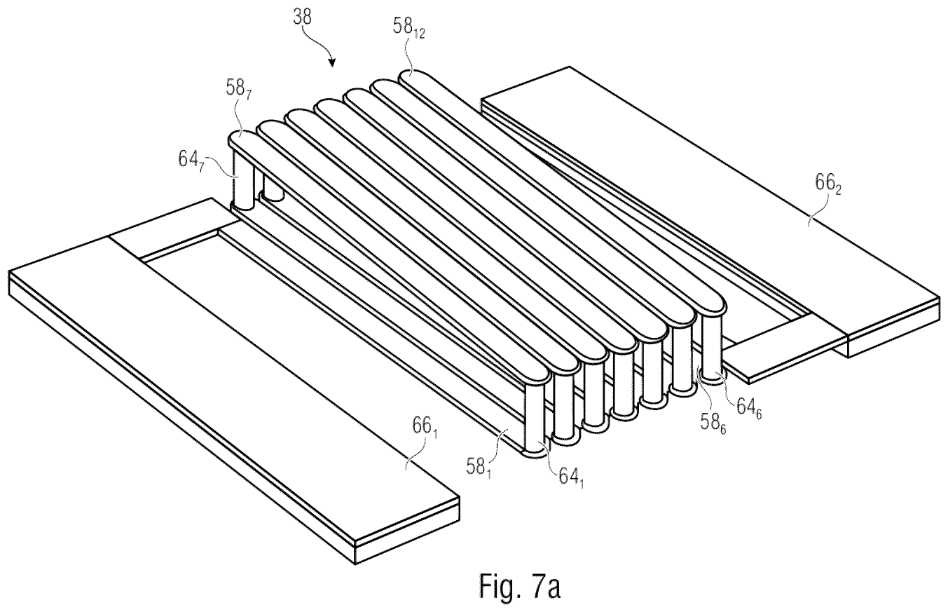

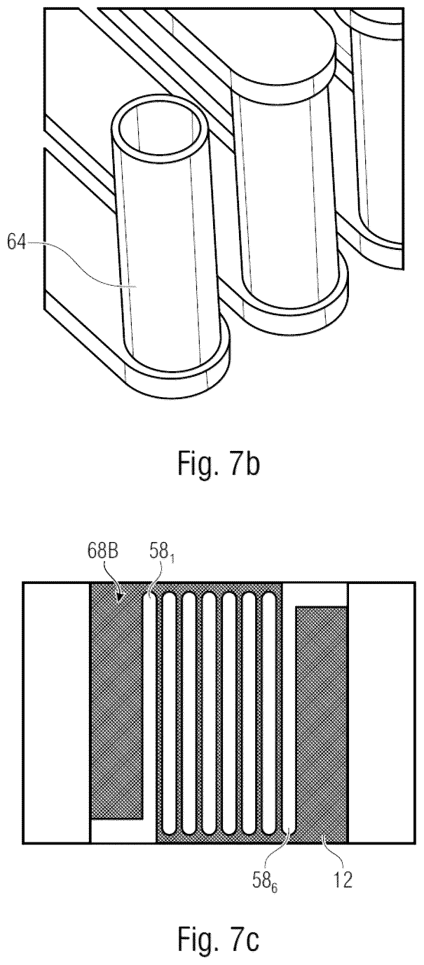

FIG. 6 shows a schematic perspective view of an apparatus 60 according to an embodiment. In this case, the apparatus 60 includes the substrate 12 having integrated therein the porous body 18. Furthermore, the heat source structure 14 includes the passive element 38 exemplarily formed as an electrically conductive coil wound around the porous body 18 as a coil core. For example, six windings are provided. Advantageously, they may be formed so that conductor paths 58₁, 58₂, 58₃, 58₄, 58₅ and 58₆ extending next to each other and particularly advantageously in parallel to each other are provided. Opposite conductor paths 58₇ to 58₁₂ may be connected by means of via structures 64₁ to 64₆ so that a surrounding winding structure can be created. Further structures, such as contact pads 66₁ and/or 66₂, may be generated at one or several sides of the substrate 12. Through this, e.g. completion of the coil structure by adding the conductor paths 58₇ to 58₁₂ to the remaining structures may be done at a later point in time, e.g. by arranging the conductor paths 58₇ to 58₁₂ on a further substrate that is then contacted directly or indirectly with the substrate 12.

In both cases, the heat source structure may form at least a coil part of an electrical coil structure. The coil part may be integrated fully or partially into the substrate 12. The coil part may include conductor paths 58₁ to 58₆ extending in parallel, wherein each conductor path element may be contacted with a via structure 64 at a first conductor path end and a second opposite conductor path end. The via structures 64 may define connection areas for further conductor path elements 58₇ to 58₁₂, wherein a combination of conductor path elements 58₁ to 58₆ on the one hand and 58₇ to 58₁₂ on the other hand may at least partially form the coil structure by adding the via structures. A number of windings may be set arbitrarily, and only slightly depends on a design height of the apparatus 50 or does not depend on it at all.

In other words, FIG. 6 shows a coil with a porous core that does not extend across the entire thickness of the substrate in this embodiment. A remaining thickness of silicon may remain on the side of the first conductor paths 58₁ to 58₇. The integrated active component according to FIGS. 3a and 3b is located in this silicon layer, or in this plane. In this case, prior to manufacturing the coil, the active component is generated by means of conventional semiconductor processes. The first conductor paths 58₁ to 58₆ on the upper substrate main side extend across the same, or are directly contacted on the active component. This distance between the conductor paths enable a passage of the fluid towards the porous core. This may also be used to cool the porous core.

FIG. 7a shows a schematic perspective view of a part of the apparatus 60, in particular, to illustrate the conductor path structures 58₁ to 58₁₂ that may be connected by via structures 64₁ to 64₇. Contact pads electrically connected to the coil structure may enable simple electrical contacting.

FIG. 7b shows an exemplary partial section of the illustration of FIG. 7a to describe in more detail an embodiment of the via structures. According to an embodiment, they may be formed as hollow cylinder structures, which enables a minor occurrence or a minor influence of skin effects.

FIG. 7c shows a schematic top view of a main side 68b of the apparatus 60 illustrated in FIG. 6. It can be seen that the substrate 12 extends beyond the conductor paths 58₁ to 58₆, and the via structures extend through the substrate 12, or are embedded in the same, for example. With reference to FIG. 6, the porous body 18 may be integrated into the substrate 12. The porous body may be surrounded by the electrical coil structure and may provide a coil core. Optionally, the coil structure may be integrated monolithically with an active element on a mutual substrate, as described for the apparatus 30₁ and 30₂, for example.

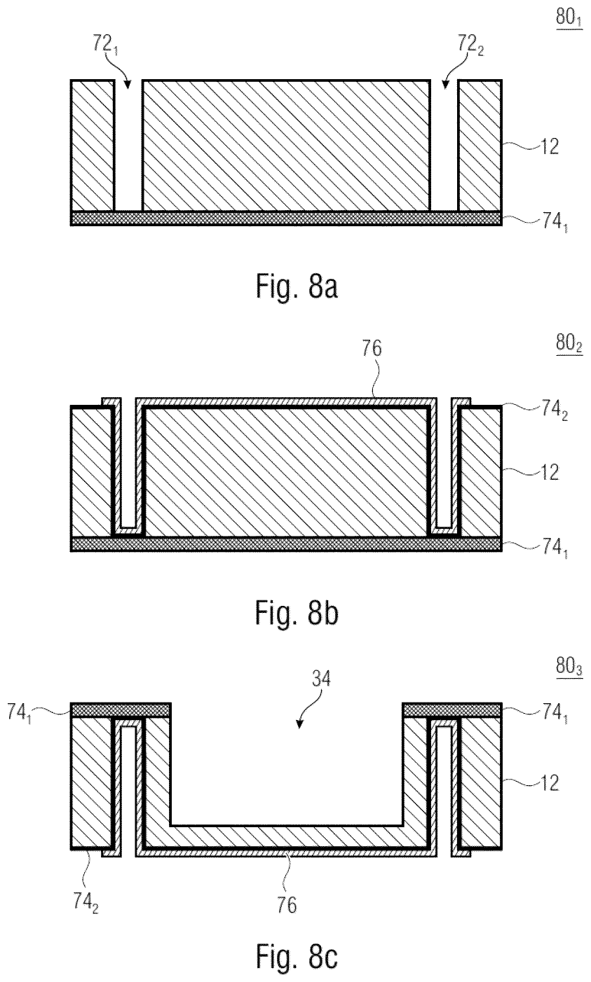

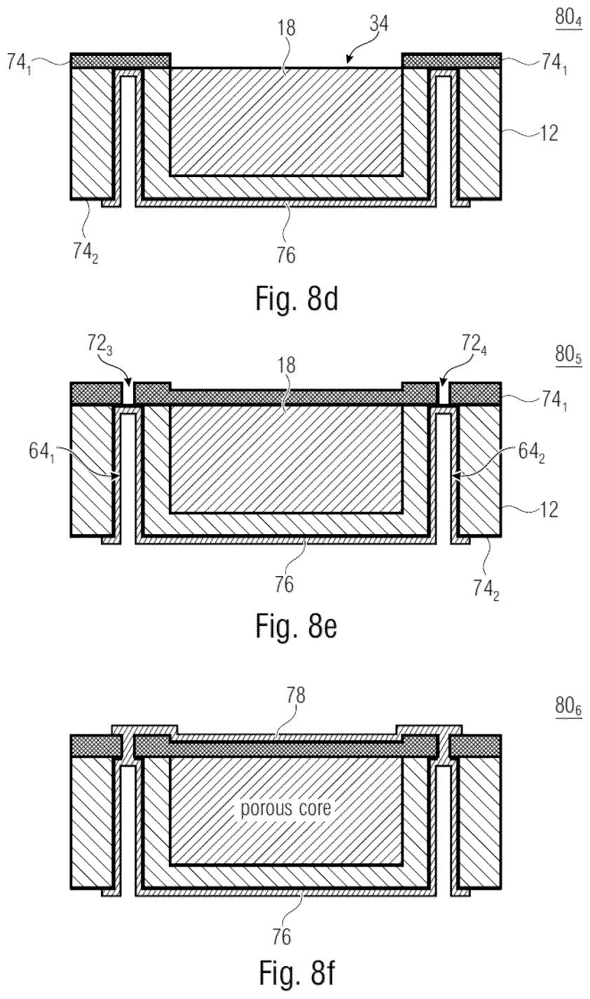

For example, a concept for embedding the porous body as a coil core into a coil structure is described on the basis of FIGS. 8a to 8f. FIG. 8a shows a schematic side-sectional view of the substrate 12 into which openings or trenches 72₁ and 72₂ may be introduced, e.g. so as to later generate the via structures. The substrate 12 may be covered on one side or on both sides by a passivation layer 74₁ so as to simplify processing. For example, the passivation layer 74₁ may provide an etch stop layer for dry etching or the like with which the trenches 72₁ and 72₂ are generated. The structure 80₁ illustrated in FIG. 8a may be further processed.

In other words, FIG. 8a shows a state after the etching of holes in the Si substrate by means of so-called Deep Reactive Ion Etching (DRIE), defining the shape and position of the vias. The holes may extend through the entire substrate or they may end in a passivation on the rear side.

FIG. 8b shows possible further processing towards a structure 80₂ that may comprise a metallization 76, compared to the illustration of FIG. 8a, e.g. so as to generate conductor paths 58 and via structures 64 for the apparatus 60. To this end, an additional passivation layer 74₂ may be arranged between the metallization 76 and the substrate 12.

In other words, FIG. 8b shows depositing and structuring a first metal layer so as to generate the first conductor paths and the via structures (hollow cylinder structures).

FIG. 8c shows a schematic side-sectional view of a structure 80₃ that may be obtained from the structure 80₂, e.g. by generating the recess 34 at a side opposite the metallization 76.

In other words, FIG. 8c shows a turned substrate and a generation of a cavity in Si by means of DRIE. Si remains below the cavity, i.e. the substrate is not etched through.

FIG. 8d shows a schematic side-sectional view of a structure 80₄, wherein the porous body 18 is introduced into the recess 34. For example, this may be carried out by filling in particles to be solidified and by subsequently solidifying them, e.g. by performing atomic layer deposition, so as to solidify the multitude of particles to become the porous body. According to alternative embodiments, the porous body 18 may be placed into the recess 16 and may be glued or fixed in another way.

In other words, FIG. 8d shows filling the cavity with soft magnetic powder and agglomerating the particles to become a porous structure.

FIG. 8e shows a schematic side-sectional view of a structure 80₅, e.g., that may be obtained by passivation of the structure 80₄ so that the recess 34 is enclosed by means of a passivation layer. This may use the same material as arranged in the passivation layer 74₁, e.g. silicon oxide or silicon nitride. However, this is not necessarily required; other materials may also be arranged. FIG. 8e exemplarily illustrates that the passivation illustrated in FIG. 8e is exposed in areas in which the passivation layer 74₁ was already arranged in previous steps or has remained. Openings 72₃ and 72₄, e.g. configured to be round, may be introduced into the passivation layer 74₁ and 74₂ in areas of the via structures 64₁ and 64₂. These openings may reach down to the bottom of the vias. With reference to FIG. 7b, such contact holes may be arranged on the bottom side between the bottom of the round via 64 and the metal path 58₁ according to FIG. 7a.

In other words, FIG. 8e shows depositing a passivation on the porous structure and generating contact holes for the metal by means or RIE (reactive iron etching).

FIG. 8f shows a schematic side-sectional view of a structure 80₆ according to an embodiment, which may be obtained from the structure 80₅, for example. A metallic structure 78 that may provide the opposite conductor paths for the coil structure and with respect to the metallization 76, for example, may be generated by means of a metallization step. By structuring the metallization 76 and/or 78, the conductor paths may be defined and the coil structure may therefore be adjusted in detail with respect to its property.

In other words, FIG. 8f shows depositing and structuring a second metallization layer to generate the second conductor paths.

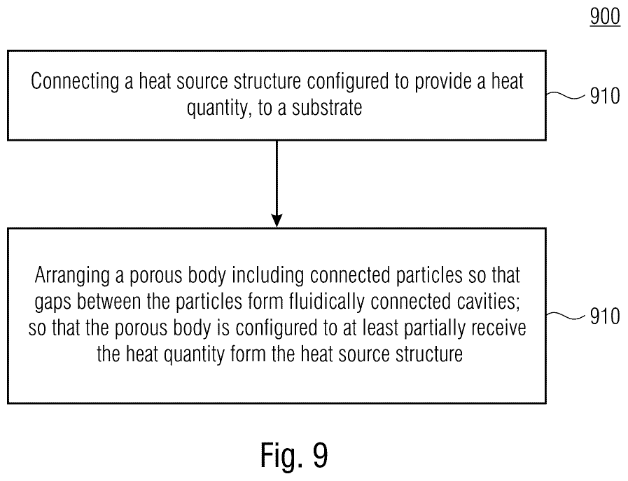

FIG. 9 shows a schematic flow diagram of a method 900 for providing an apparatus according to an embodiment. Step 910 of the method 900 includes connecting, to a substrate, a heat source structure configured to provide a heat quantity. Step 920 includes arranging a porous body including connected particles so that gaps between the particles form fluidically connected cavities. The method is carried out so that the porous body is configured to at least partially receive the heat quantity of the heat source structure.

Embodiments concern porous bodies that may be configured with a technological method that includes generating microstructures made of powder by agglomeration by means of atomic layer deposition (ALD) at low temperatures, for example. Such microstructures may be fee of shrinkage and may be compatible with so-called BEOL (back end of line) standard processes at temperatures of up to 400° C. By using such a method, cores may be manufactured for integrated coils with low eddy current losses at high frequencies.

Porous microstructures corresponding to embodiments comprise a high thermal stability. Porous micro-magnets agglomerated from NdFeB powder may withstand temperatures of up to 400° C. without degradation. Also, such structures made of soft magnetic materials, e.g. for the use as coil cores, may also show a comparable behavior. In addition, the intrinsic porosity of microstructures may be used for their active cooling. For example, such structures may be used in a phosphor converter that may be manufactured from fluorescent particles, by using air as a cooling medium that flows through the porous body.

Embodiments concern the use of coils with a porous core manufactured by means of agglomeration of a soft magnetic powder by means of ALD. Through this, electronic circuits with particularly high thermal stability may be realized. FIGS. 5a and 5b show two possible implementations as examples. The heat released in the active component 36 and the core 38 is dissipated by a heat sink, the coating body 62 below the carrier (interposer). In FIG. 5a the coil and the active element are discretely mounted on the carrier, e.g. by flip-chip bonding. If the coil has been manufactured using a substrate with high thermal conductivity, such as silicon, its effective heat dissipation is ensured. Even if the heat released in the active component heats up the coil additionally, it can be assumed that the capacity of the circuit is determined by the active component or other parts, however, not by the coil with the porous core. To improve heat dissipation of the coil, it is directly integrated into the carrier in FIG. 5b. Thus, e.g. in a possible implementation, a GaN-on-Si substrate may be used for active components on the basis of gallium nitrate (GaN), and the inductance may be realized with the silicon substrate of the GaN-on-Si wafer so as to efficiently use the surface area. On the one hand, this may be done from the front side by exposing the area needed for the coil.

Alternatively and particularly space-efficient, the coil may also be arranged or generated on the rear side of the substrate below the active component. A combination of both methods for the realization of large coil thicknesses or transformer structures is also possible. For example, when realizing so-called high electro mobility transistors (HEMT) with a lateral current flow, the rear-side area is available to realize coils. In an active realization of vertical components, a part of the wafer area on the rear side may be used for inductances since the ohmic resistance of the remaining area may be realized in a sufficiently low-impedance way.

In addition, monolithic integration enables a decrease of the parasitic elements of the commutation circuit for the load current and enables an increase of the switching frequency and further miniaturization.

Furthermore, mutual arrangement on a substrate enables a new additional degree of freedom in the implementation of the commutation loops for the load current. Thus, the arrangement may be positioned with respect to each other in an optimum way so that additional commutation loops and parasitic capacitive effects may minimized.

In the embodiment according to FIG. 4a, the porous core of the coil integrated directly into the carrier is used as a cooling loop and is traversed by a cooling medium 26 for heat dissipation. This does not only allow better cooling of the coil. This achieves a higher overall cooling effect than would be the case with a conventional heat sink according to FIGS. 5a and 5b. In addition, by arranging the coil directly below the active component, the surface area of the circuit is reduced. A gas or a liquid may be used as a cooling medium. In FIGS. 3a and 3b, the active component and the coil are integrated into the carrier. While FIG. 4a exemplary shows the integration of an active component releasing significant heat quantities with a coil with a porous body on a carrier (interposer) made of a thermally conductive material, wherein the porous body to cool the body as well the entire arrangement is traversed by a cooling medium, FIGS. 3a and 3b show a comparable structure wherein the active element is also integrated into the substrate.

In principle, the active elements or active components according to embodiments described herein may be any component of an electronic circuit that releases heat in its operation, for example. For example, this may be a GaN power transistor, or the electronic circuit of a voltage converter module. By means of the integration of power transistors and inductances on a base material, such as GaN-FET (FET=field effect transistor) and a coil on, or in, a silicon carrier wafer, circuits with high power densities and low space requirements may be realized. However, the active component may be an LED and an integrated circuit, in particular according to FIGS. 3a and 3b.

Alternatively, embodiments with more than one coil are possible. In this way, in case of a suitable core geometry, e.g., transformer arrangements in, or on, the interposer may be arranged. They may also be cooled actively by having a cooling medium flow through the porous core material.

Alternatively, the inductance may also be realized in a PCB or DCB, and the active component may be positioned above the coil. This arrangement may be used in modules for power converters and enables, e.g., a symmetrification of pulse currents. This is particularly advantageous in the use of so-called wide bandgap semiconductor components in converters since high voltage slopes and overvoltage stress may occur and these may be minimized.

Embodiments enable the use of coils with a porous core manufactured by agglomeration of powder by means of ALD, enabling the operation of electronic circuits at much higher temperatures compared to conventional components. The porosity of the core material may be used to actively cool the electronic circuit by means of a cooling medium flowing therethrough. The surface area of an electronic circuit may be further decreased compared to known concepts. The power density of an electronic circuit may be increased compared to known concepts. In embodiments, the space-saving monolithic integration of inductances with active components is enabled on a mutual substrate such as GaN-on-Si. Furthermore, embodiments enable a space-efficient monolithic vertical arrangement of transistors or diodes and inductances. Embodiments enable high switching frequencies of integrated solutions due to shorter connection lengths and less parasitic elements.

Even though some aspects have been described within the context of a device, it is understood that said aspects also represent a description of the corresponding method, so that a block or a structural component of a device is also to be understood as a corresponding method step or as a feature of a method step. By analogy therewith, aspects that have been described within the context of or as a method step also represent a description of a corresponding block or detail or feature of a corresponding device

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### BIBLIOGRAPHY

[1] http://www.analog.com/en/analog-dialogue/articles/digital-isolation-solutions-to-designproblems.html
[2] N. Wang et al., “High frequency DC-DC converter with co-packaged planar inductor and power IC”, Proc. ECTC Conf., Las Vegas, NV, USA, 2013
[3] R. Meere et al., “Analysis of microinductor performance in a 20-100 MHz DCDC converter”, Transactions on Power Electronics, Vol. 24, No. 9, 2009
[4] P. R. Morrow et al., “Design and fabrication of on-chip coupled inductors integrated with magnetic material for voltage regulators”, Transactions on Magnetics, Vol. 47, No. 6, 2011

1. Apparatus, comprising:
a substrate;
a heat source structure connected to the substrate and configured to provide a heat quantity; and
a porous body comprising particles connected by a coating, wherein gaps between the particles form fluidically connected cavities;
wherein the porous body is configured to at least partially receive the heat quantity of the heat source structure.

2. Apparatus according to claim 1, wherein the coating comprises a layer deposited by atomic layer deposition.

3. Apparatus according to claim 1, wherein, for a passage of a fluid, the porous body comprises an entry area for an entry of the fluid and an exit area for fluidically coupled to the entry area by means of the fluidically connected cavities for an exit of the fluid; and is configured to release during the passage at least a part of the received heat quantity to the fluid so as to cool the porous body.

4. Apparatus according to claim 3, configured to generate the passage at least partially on the basis of the released heat quantity.

5. Apparatus according to claim 3, configured to generate the passage at least in part actively.

6. Apparatus according to claim 3, wherein the substrate comprises a fluidic opening configured to let a fluid through towards the entry area and/or away from the exit area.

7. Apparatus according to claim 6, wherein the porous body comprises first particles forming connected first cavities; and
wherein a porous structure comprising connected second particles is arranged in an area of the fluidic opening, wherein gaps between the second particles form fluidically connected second cavities.

8. Apparatus according to claim 7, wherein the second particles comprise an non-magnetic material.

9. Apparatus according to claim 6, wherein the porous body provides a filter structure so as to filter the fluid.

10. Apparatus according to claim 1, wherein the porous body provides at least a part of a functional element providing a function of the apparatus and being configured to maintain the function under the impact of the heat source structure.

11. Apparatus according to claim 10, wherein the functional element is associated with an operation of the heat source structure.

12. Apparatus according to claim 10, wherein the functional element comprises an electrical coil, wherein the porous body comprises soft magnetic particles and is arranged as a coil core of the electrical coil.

13. Apparatus according to claim 1, wherein the heat source structure is configured to heat a local area of the porous body to a temperature of at least 250° C.

14. Apparatus according to claim 1, wherein the porous body is thermally stable for a temperature of at least 250° C.

15. Apparatus according to claim 1, wherein the heat source structure comprises an active element configured to generate at least a part of the heat quantity under the impact of electrical energy.

16. Apparatus according to claim 15, wherein the active element comprises a light-emitting diode and/or a diode and/or a transistor and/or an integrated circuit.

17. Apparatus according to claim 1, wherein the heat source structure comprises at least a part of an electrically passive element, wherein the electrically passive element is configured to generate at least a part of the heat quantity under the impact of electrical energy.

18. Apparatus according to claim 17, wherein the electrically passive element comprises an electrical coil.

19. Apparatus according to claim 18, wherein the heat source structure forms a part of the electrical coil; or forms an electrical coil.

20. Apparatus according to claim 18, wherein the particles of the porous body comprise a soft magnetic material, and the porous body is arranged as a coil core of the electrical coil.

21. Apparatus according to claim 17, wherein the heat source structure comprises an active element configured to generate at least a part of the heat quantity under the impact of electrical energy.

22. Apparatus according to claim 21, wherein at least one coil winding of an electrical coil extends around the active element.

23. Apparatus according to claim 1, wherein the heat source structure comprises an active element and at least a part of an electrically passive heat source.

24. Apparatus according to claim 1, wherein the porous body is at least partially integrated into the substrate.

25. Apparatus according to claim 1, wherein the substrate comprises a printed circuit board (PCB) and/or a direct bonded copper (DBC, or direct copper bond, DCB)), and/or a semiconductor material and/or a glass material.

26. Apparatus according to claim 1, wherein the heat source structure forms at least a coil part of an electrical coil structure.

27. Apparatus according to claim 26, wherein the coil part is at least partially integrated into the substrate.

28. Apparatus according to claim 26, wherein the coil part comprises first conductor path elements extending in parallel, wherein each conductor path element is contacted with a via structure at a first conductor path end and a second opposite conductor path end; wherein the via structures define connection areas for second conductor path elements, wherein a combination of the first conductor path elements, the via structure, and the second conductor path elements at least partially forms the electrical coil structure.

29. Apparatus according to claim 28, wherein the via structures comprise hollow cylinder structures.

30. Apparatus according to claim 26, wherein the porous body is arranged so that the electrical coil structure is wound around it in order to provide a coil core.

31. Apparatus according to claim 26, wherein the coil structure is monolithically integrated with an active element on the mutual substrate.

32. Apparatus according to claim 1, comprising a cooling body connected to the substrate in a thermally conductive manner.

33. Method for providing an apparatus, comprising:
connecting, to a substrate, a heat source structure configured to provide a heat quantity; and
arranging a porous body comprising particles connected by a coating so that gaps between the particles form fluidically connected cavities;
so that the porous body is configured to at least partially receive the heat quantity of the heat source structure.

34. Method according to claim 33, further comprising:
introducing a multitude of particles into a recess of the substrate; and
performing atomic layer deposition to generate the coating and to solidify the multitude of particles to become the porous body.
